(19) United States
(12) Patent Application Publication
(10) Pub. No.: US 2019/0280016 A1
(43) Pub. Date: Sep. 12, 2019

(54) MANUFACTURING METHOD OF ARRAY SUBSTRATE AND ARRAY SUBSTRATE

(71) Applicants: HKC Corporation Limited, Shenzhen (CN); Chongqing HKC Optoelectronics Technology Co., Ltd., Chongqing (CN)

(72) Inventors: Entsung Cho, Shenzhen, Guangdong (CN); Qionghua Mo, Shenzhen, Guangdong (CN)

(21) Appl. No.: 16/253,440

(22) Filed: Jan. 22, 2019

Related U.S. Application Data
(63) Continuation of application No. PCT/CN2018/113606, filed on Nov. 2, 2018.

(30) Foreign Application Priority Data
Mar. 9, 2018 (CN) 201810196074.5

(51) Int. Cl. H01L 27/12

(52) U.S. Cl. CPC H01L 27/127; H01L 27/1288; H01L 27/1222

(57) ABSTRACT

The present disclosure discloses a manufacturing method of an array substrate, which includes the following operations: patterning a photoresist layer to form a first region, a second region and a third region; patterning a source-drain electrode layer and a semiconductor layer to form a source electrode, a drain electrode and a channel region corresponding to the covering portions of the first region, the second region and the third region.

### CROSS REFERENCE TO RELATED APPLICATIONS

The present application is a Continuation Application of PCT Application No. PCT/CN2018/113606 filed on Nov. 2, 2018, which claims the benefit of Chinese Patent Application No. 201810196074.5 filed on Mar. 9, 2018. All the above are hereby incorporated by reference.

### FIELD

Embodiments of the present disclosure relate to active switching technology, and in particular, relates to a manufacturing method of an array substrate and an array substrate.

### BACKGROUND

Active switch is a key device of a display panel and plays a very important role in the performance of display panel. With the rapid development of electronic equipment, electronic equipments of lower power consumption and better endurance are required, as well as display panels of lower power consumption in electronic equipments.

A display panel is defined with an active switch array substrate. However, at present, the leakage current of the active switch of the active switch array substrate is relatively large, and when light irradiates the active switch, photogenerated carriers will also be generated, further increasing the leakage current of the active switch and resulting in higher power consumption of the display panel and poor stability of the active switch.

### SUMMARY

Embodiments of the present disclosure provide a manufacturing method of an array substrate and an array substrate to reduce leakage current of an active switch of the array substrate and improve stability of the active switch.

Embodiments of the present disclosure provide a manufacturing method of an array substrate, the array substrate includes a plurality of active switches, and the manufacturing method of the array substrate includes:

providing a substrate;

forming a gate electrode, a gate insulating layer, a semiconductor layer, a source-drain electrode layer and a photoresist layer all on the substrate;

patterning the photoresist layer to form a patterned photoresist layer, and the patterned photoresist layer includes a first region, a second region, and a third region between the first region and the second region, and the thickness of the third region ranges from 0.2 microns to 0.8 microns; and,

patterning the source-drain electrode layer by using the patterned photoresist layer as a mask, forming a source electrode of the active switch in a portion covered by the first region, forming the drain electrode of the active switch in a portion covered by the second region, patterning the semiconductor layer, and forming a channel region of the active switch in the portion covered by the third region.

Embodiments of the present disclosure also provides an array substrate which is defined with a plurality of active switches, the active switch is formed by the manufacturing method provided above, and the active switch includes:

a substrate;

a semiconductor layer, a source electrode and a drain electrode all formed on the substrate;

and the source electrode and the drain electrode are located on one side of the semiconductor layer away from the substrate;

the distance between the projection profile of the semiconductor layer on the substrate and the projection profile of the source electrode or the drain electrode on the substrate ranges from 0 to 1.5 microns; the distance between the projection profile of the doping layer on the substrate and the projection profile of the source electrode or the drain electrode on the substrate ranges from 0 to 1.0 microns.

The manufacturing method of the array substrate provided in some embodiments of the present disclosure may reduce the portions of the semiconductor layer of the active switch beyond the source electrode and the drain electrode, reducing light absorption of the semiconductor layer in the active switch, the probability of generating photo-generated carriers, and the leakage current of the active switch. Thus the manufacturing method may correspondingly improve and the stability of the active switch, when the active switch is used in a display panel, power consumption of the display panel may also be reduced.

### BRIEF DESCRIPTION OF THE DRAWINGS

In order to more clearly explain the technical scheme in the embodiments or example technologies of the present disclosure, the drawings that need to be used in the embodiments or example technical descriptions will be briefly introduced below. Obviously, the drawings in the following description are some embodiments of the present disclosure. For those of ordinary skill in the art, other drawings may be obtained from these drawings without paying creative labor.

FIG. 1 is a schematic structural diagram of an active switch of the array substrate in prior art;

FIG. 2 is a flowchart of a manufacturing method of an array substrate provided in some embodiments of the present disclosure;

FIG. 3 is a schematic diagram of the principle of patterning a photoresist layer provided in some embodiments of the present disclosure;

FIG. 4 is a schematic diagram of the relationship between the exposure energy and the remaining thickness of the photoresist layer provided in some embodiments of the present disclosure;

FIG. 5 is a top view of a photoresist layer after being patterned according to some embodiments of the present disclosure;

FIG. 6 is a cross-sectional view taken along the section line B-B′ in the top view of FIG. 5;

FIG. 7 is a schematic diagram of the remaining thicknesses of the third regions of the photoresist layers of six different samples provided in some embodiments of the present disclosure;

FIG. 8 is a schematic diagram of a film layer structure after deposition of the photoresist layer in an manufacturing method of an array substrate provided in some embodiments of the present disclosure;

FIG. 9 is a schematic diagram of a film layer structure after patterning of the photoresist layer in a manufacturing method of an array substrate provided in some embodiments of the present disclosure;

FIG. 10 is a schematic diagram of a film layer structure after the first wet etching in the manufacturing method of the array substrate provided in some embodiments of the present disclosure;

FIG. 11 is a schematic diagram of a film layer structure after the first dry etching in the manufacturing method of the array substrate provided in some embodiments of the present disclosure;

FIG. 12 is a schematic diagram of a film layer structure after photoresist ashing in the manufacturing method of the array substrate provided in some embodiments of the present disclosure;

FIG. 13 is a schematic diagram of a film layer structure after the second wet etching in the manufacturing method of the array substrate provided in some embodiments of the present disclosure;

FIG. 14 is a schematic diagram of a film layer structure after the second dry etching in the manufacturing method of the array substrate provided in some embodiments of the present disclosure;

FIG. 15 is a schematic diagram of the etching direction of the photoresist layer of the array substrate provided in some embodiments of the present disclosure;

FIG. 16 is a schematic structural diagram of an array substrate provided by some embodiments of the present disclosure;

FIG. 17 is a schematic structural diagram of an active switch of an array substrate according to some embodiments of the present disclosure;

FIG. 18 is a schematic structural diagram of a liquid crystal display device provided in some embodiments of the present disclosure.

### DETAILED DESCRIPTION OF THE EMBODIMENTS

In order to make the purpose, technical scheme and advantages of the present disclosure clearer, the technical scheme of the present disclosure will be described clearly and completely by way of implementation with reference to the drawings in the embodiments of the present disclosure. Obviously, the described embodiments are part of the embodiments of the present disclosure, not all embodiments. Based on the embodiments in the present disclosure, all other embodiments obtained by a person of ordinary skill in the art without making creative work fall within the scope of protection of the present disclosure.

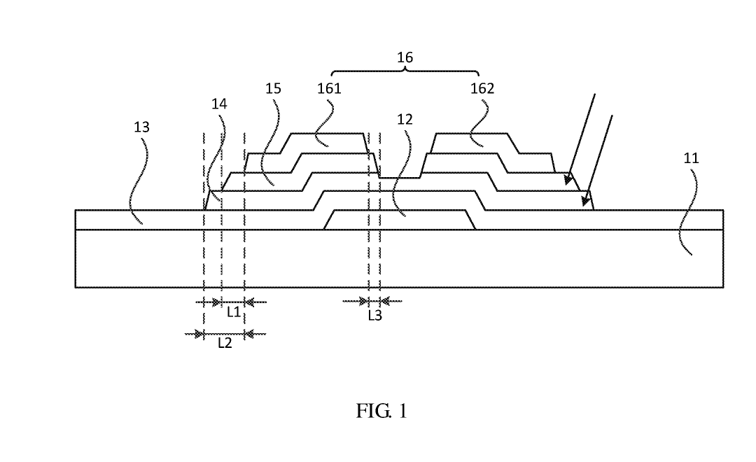

FIG. 1 is a structural diagram of an active switch of an array substrate provided in prior art. Referring to FIG. 1, the active switch includes a substrate 11, a gate electrode 12, a gate electrode insulating layer 13, an active layer 14 (which may also be referred to as an amorphous silicon layer 14 because it is commonly formed of an amorphous silicon material), a doping layer 15 and a source electrode and drain electrode 16, and the source electrode and drain electrode 16 optionally includes a source electrode 161 and a drain electrode 162, and the semiconductor layer of the active switch may include the active layer 14 and the doping layer 15. The gate electrode 12 and the source electrode 161 of the active switch, as well as the gate electrode 12 and the drain electrode 162 of the active switch are all separated by the gate electrode insulating layer 13, so the active switch is actually an insulated gate typed field effect transistor, and the active switch may be divided into N type and P type.

Herein, take the N-type active switch as an example to explain the working principle of the active switch. When a positive voltage greater than the on voltage of the N-type active switch is applied to the gate electrode 12, an electric field will be generated between the gate electrode 12 and the active layer 14. Under the action of this electric field, a conductive channel will be formed in the active layer 14 so that a conductive state will be formed between the source electrode 161 and the drain electrode 162. The larger the voltage applied to the gate electrode 12, the larger the conductive channel will be. In this condition, when a voltage is applied between the source electrode 161 and the drain electrode 162, carriers will pass through the conductive channel. When a negative voltage lower than the on voltage of the N-type active switch is applied to the gate electrode 12, no electron channel is formed in the active layer 14, and a closed state is formed between the source electrode 161 and the drain electrode 162. The doped layer 15 is formed between the active layer 14 and the source electrode 161, and formed between the active layer 14 and the drain electrode 16, being defined to reduce the resistances against the signals of active layer 14 and the source-drain electrodes 16. Those skilled in the art may understand that the functions of the substrate 11, the gate electrode 12, the gate electrode insulating layer 13, the active layer 14, the doping layer 15 and the source electrode/drain electrode 16 of the active switch provided by the embodiments of the present disclosure are similar to those of the prior art technology, which will not be described here.

In the actual manufacturing process of the active switch, the edge of the formed amorphous silicon layer 14 exceeds the edge of the source electrode and drain electrode 16, i.e. the amorphous silicon tail L2 is formed, and the edge of the formed doped layer 15 exceeds the edge of the source electrode and drain electrode 16, i.e. a tail L1 of the doped layer outside the channel and a tail L3 of the doped layer inside the channel are formed. When the active switch is applied to a liquid crystal display panel, the existence of the above three types of tails, especially the amorphous silicon tail L2, may directly contact or absorb visible light emitted by the backlight module of the liquid crystal display panel. The amorphous silicon layer 14 may react with the visible light to generate light leakage current, thereby further increasing the leakage current of the active switch, resulting in higher power consumption of the array substrate and unstable electrical performance of the active switch.

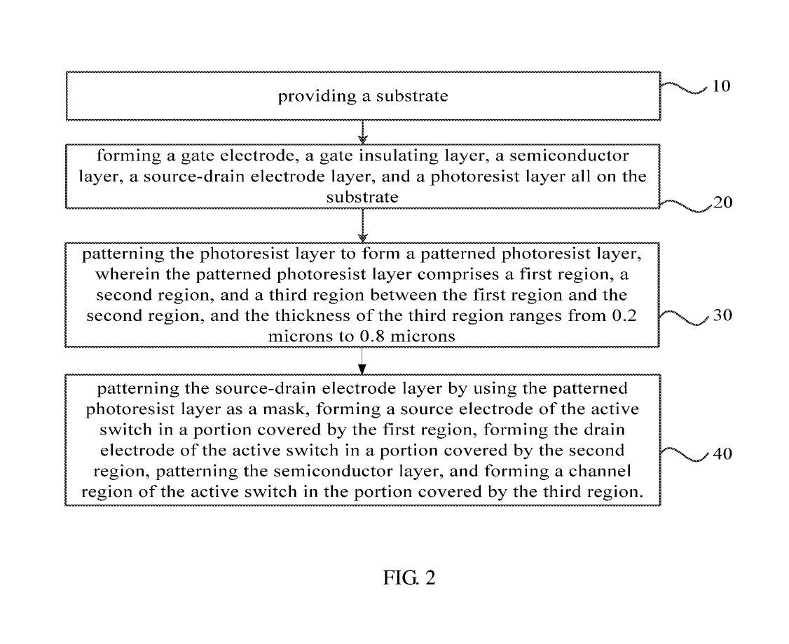

In order to solve this problem, some embodiments of the present disclosure provide a manufacturing method of an array substrate, which includes a plurality of active switches. Referring to FIG. 2, FIG. 2 is a flowchart of a manufacturing method of an array substrate provided in some embodiments of the present disclosure. The manufacturing method optionally includes:

S10, providing a substrate.

In this embodiment, the substrate may be a glass substrate or a flexible substrate such as polyimide (PI). Those skilled in the art may understand that if the application products and the application scenarios of the active switch of the array substrate are different, the substrate materials of the array substrate are different. Obviously, the substrate materials include, but are not limited to, glass substrates and flexible substrates, and any material that may be used as the array substrate falls within the scope of protection of the present disclosure.

S20, forming a gate electrode, a gate electrode insulating layer, a semiconductor layer, a source electrode-drain electrode layer and a photoresist layer on the substrate.

In this embodiment, the constituent material of the optional gate electrode is aluminum (Al) or molybdenum (Mo), the constituent material of the gate electrode insulating layer is silicon nitride (SiN), and the semiconductor layer may include an active layer and a doped layer, and the constituent material of the active layer is amorphous silicon (a˜Si), the constituent material of the doped layer is heavily doped amorphous silicon, and the optional material may include N-type amorphous silicon or P-type amorphous silicon. The constituent materials of the source-drain electrode layer are molybdenum nitride, aluminum and constituent materials of molybdenum nitride (MON/Al/MON) photoresist layers including resin, sensitizer, solvent and additive, the constituent materials are sequentially stacked, and the sensitizer is a photosensitive component in the photoresist layer, and photochemical reaction may occur to radiant energy in the form of light (especially ultraviolet region). Photoresist may be divided into positive glue and negative glue in terms of disclosure characteristics. For positive glue, the part irradiated by ultraviolet rays may be removed due to chemical property changes, while for negative glue, the part irradiated by ultraviolet rays may remain due to chemical property changes. In this embodiment, the positive glue is optionally used as an example. Those skilled in the art may understand that the constituent materials of each film layer of the array substrate include, but are not limited to, the above examples, and the constituent materials of any film layer structure of the array substrate fall within the scope of protection of the present disclosure; and the manufacturing process of each film layer structure is not specified in the present disclosure, the constituent materials of any film layer structure of the array substrate fall within the scope of protection of the present disclosure.

S30, patterning the photoresist layer to form a patterned photoresist layer, and the patterned photoresist layer includes a first region and a second region, and a third region located between the first region and the second region, and the thickness of the third region ranges from 0.2 microns to 0.8 microns.

Patterning the photoresist layer in this embodiment may includes removing portions of different thicknesses from the surface of the relatively flat photoresist layer by using exposure and development technique, thereby forming a patterned (uneven) photoresist layer. The patterned photoresist layer includes the above three regions divided according to the different thicknesses of the photoresist layer and the different functional areas of the active switch.

And The thickness of the third region ranges from 0.2 microns to 0.8 microns 0.2 microns to 0.8 microns, which may ensure that the photoresist of the third region is completely etched in the subsequent etching process, that is, when the active switch corresponding to the third region are completely exposed, the remaining thickness and lateral dimensions of the first region and the second region ensure that their corresponding active switch structure may be effectively covered.

S40. patterning the source-drain electrode layer by using the patterned photoresist layer as a mask, forming the source electrode of the active switch in the portion covered by the first region, forming the drain electrode of the active switch in the portion covered by the second region, patterning the semiconductor layer, and forming the channel region of the active switch in the portion covered by the third region.

Optionally, patterning the source-drain electrode layer includes at least one wet etching of the source-drain electrode layer; the patterning of the semiconductor layer includes at least one dry etching of the semiconductor layer.

In this embodiment, wet etching may include etching the source-drain electrode layer with a mixed solution of phosphoric acid (H₃PO₄), acetic acid (CH₃COOH) and nitric acid (HNO₃), and etching the semiconductor layer (including the active layer and the doped layer) with vacuum plasma. The etching gas may include a mixed gas of sulfur hexafluoride (SF₆) and chlorine (Cl₂) or a mixed gas of sulfur hexafluoride (SF₆), oxygen (O₂) and helium (He).

Optionally, a halftone mask process is used to pattern the photoresist layer, and the required illumination energy corresponding to the exposure of the third region ranges from 37 millijoules (mJ) to 48 millijoules (mJ).

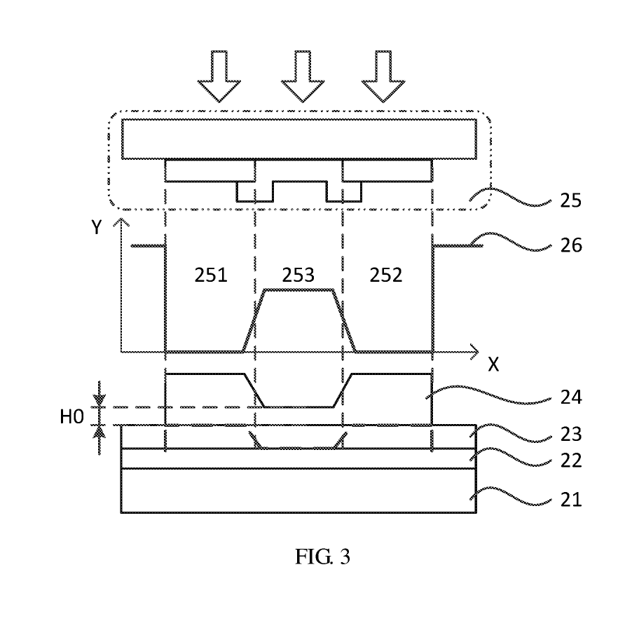

Optionally, FIG. 3 is a schematic diagram of the principle of patterning a photoresist layer provided in some embodiments of the present disclosure. Referring to FIG. 3, the exposed sample optionally includes a photoresist layer 24, a source-drain electrodes layer 23, other functional layers 22 (which may include a semiconductor layer, a gate electrode insulating layer, and a gate electrode layer, shown generally at 22 in FIG. 3) and a substrate 21. The halftone mask 25 may optionally include three regions, the first region 251 corresponding to the source electrode formation region of the exposed sample, the second region 252 corresponding to the drain electrode formation region of the exposed sample, and the third region 253 located between the first region 251 and the second region 252 corresponding to the channel formation region of the exposed sample. Since the first region 251, the second region 252, and the third region 253 of the halftone mask 25 have different light transmittance, the exposure degrees of the photoresist layer 24 after incident light passing through the halftone mask 25 are different, thereby forming the patterned photoresist layer 24. In FIG. 3, in the X-Y coordinate system, X represents different positions of the exposed sample (mainly referring to the photoresist layer 24) corresponding to the halftone mask (in nanometers or micrometers, which is according to the actual requirements of the active switch without limitation), Y represents exposure energy (in millijoules), and the fold line 26 represents the change trend of exposure energy corresponding to different positions. The photoresist layer 24 corresponds to the positions of the first region 251 and the second region 252 of the halftone mask 25. Since the light passing through the halftone mask 25 is less, the corresponding exposure energy is less, the removed portion of the photoresist layer 24 is less, and the corresponding remaining thickness is thicker. The photoresist layer 24 corresponds to the position of the third region 253 of the halftone mask 25. Since there is more light passing through the halftone mask 25, the corresponding exposure energy is larger, and the photoresist layer 24 is removed more and the corresponding remaining thickness is thinner (HO shows the remaining thickness of the photoresist layer 24 in FIG. 3). The photoresist layer 24 has different thickness corresponding to different positions to form a patterned photoresist layer 24.

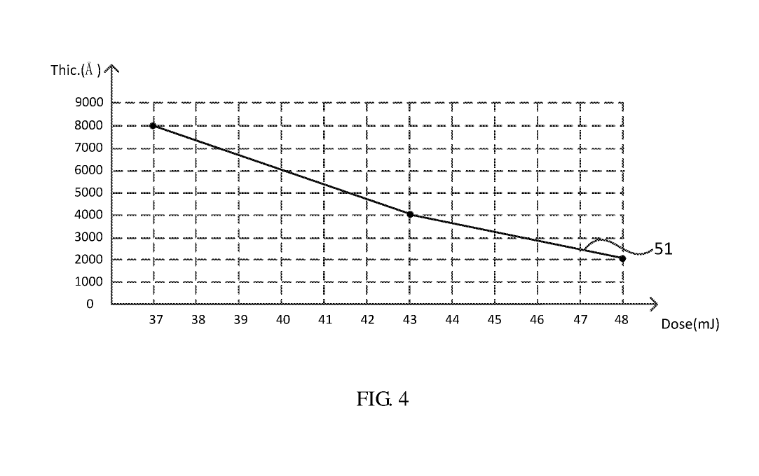

Optionally, FIG. 4 is a schematic diagram of the relationship between the exposure energy and the remaining thickness of the photoresist layer provided in some embodiments of the present disclosure. Referring to FIGS. 3 and 4, the horizontal axis represents the exposure energy dose in millijoules (mJ), and the vertical axis represents the remaining thickness Thic. of the photoresist layer 24 in Amy (Å) and the fold line 51 represents the corresponding relationship between the remaining thickness Thic. of the photoresist layer 24 and the exposure energy dose. By controlling the exposure energy dose in the range of 37 mJ-48 mJ, the photoresist layer 24 may retain a thickness Thic. of 2000 Å-8000 Å, i.e., 0.2-0.8 microns.

Optionally, when the value of the remaining thickness Thic. of the photoresist layer 24 ranges from 0.4 to 0.8 microns, the required exposure energy Dose is 1.5 mJ for every 0.1 micron decrease in the remaining thickness Thic. of the photoresist layer 24. When the value of the remaining thickness Thic of the photoresist layer 24 is in the range of 0.2 to 0.4 microns, the required exposure energy Dose is 2.5 mJ for every 0.1 micron decrease in the remaining thickness Thic of the photoresist layer 24. Therefore, it is necessary to control the value of the appropriate exposure energy according to the remaining target thickness of the photoresist layer 24.

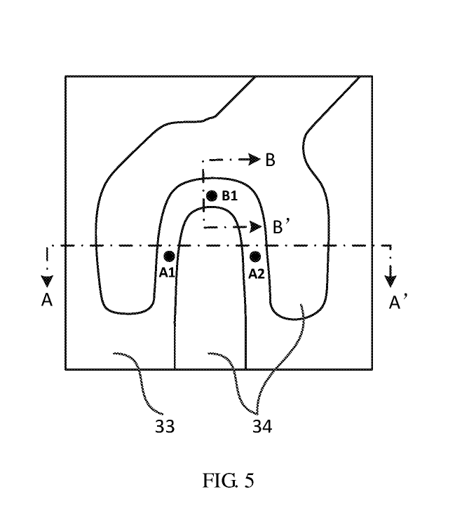

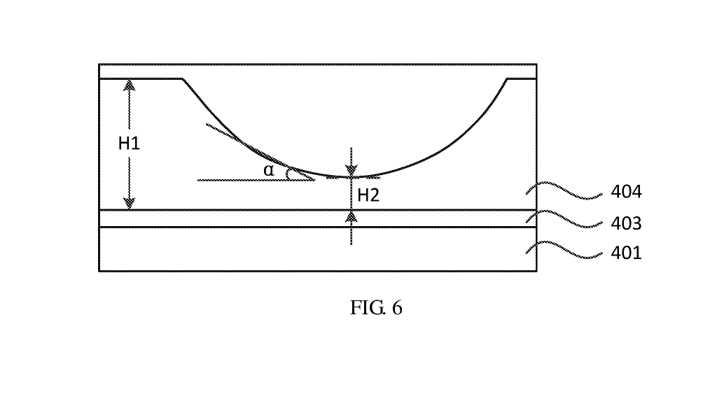

Optionally, FIG. 5 is a top view of the patterned photoresist layer provided in some embodiments of the present disclosure. Referring to FIG. 5, a first region and a second region of the photoresist layer are optionally shown at 34 in FIG. 5, and a third region of the photoresist layer is shown at 33. The locations where the thickness remains the smallest in the third region of the photoresist layer 24 are optionally shown at points A1, A2 and B1. Specifically, FIG. 6 is a schematic cross-sectional structure along section lines B-B′ in the top view of FIG. 5. Referring to FIG. 6, a multi-layer functional layer 403 (which may include a gate electrode, a gate electrode insulating layer, a semiconductor layer and a source-drain electrodes layer, which are not specifically divided in FIG. 6 and are all shown at 403) and a photoresist layer 404 are formed on the substrate 401. With reference to FIGS. 5 and 6, extending toward the first and second regions of the photoresist layer 404 with the location of the minimum thickness remaining in the third region of the photoresist layer 404 (i.e., the location indicated by A1, A2, and B1 in FIG. 5, i.e., the location indicated by H2 in FIG. 6) as the midpoint, a pit-like cross section may be obtained, as shown in FIG. 6.

Optionally, the remaining thickness Hl of the first region and the second region of the photoresist layer 404 is 1.8 microns to 2.2 microns.

Optionally, the angle a between the pit surface of the photoresist layer 404 and the interface between the photoresist layer 404 and the multilayer functional layer 403 ranges from 28° to 32°.

Optionally, the remaining thickness Hl of the first and second regions of the photoresist layer 24 microns is 2.174 microns, the minimum remaining thickness H2 of the third region is 0.54 microns, and the included angle a between the pit surface and the interface between the photoresist layer 404 and the multilayer functional layer 403 is 30.69°.

Optionally, the third region of the photoresist layer has a thickness uniformity value ranging from 25% to 55%.

Among them, uniformity characterizes the flatness of the retained thickness of the third region, and optionally, the numerical calculation method of uniformity may adopt the following formula:

$$U \% = \vert \frac{H max - H min}{H max - H min} \vert \times 100 \%$$

Among them, Hₘₐₓ represents the maximum value of the retained thickness of the third region and Hₘᵢₙ represents the minimum value of the retained thickness of the third region. The smaller the value of U % of the uniformity, the better the uniformity of the remaining thickness of the third region of the photoresist layer.

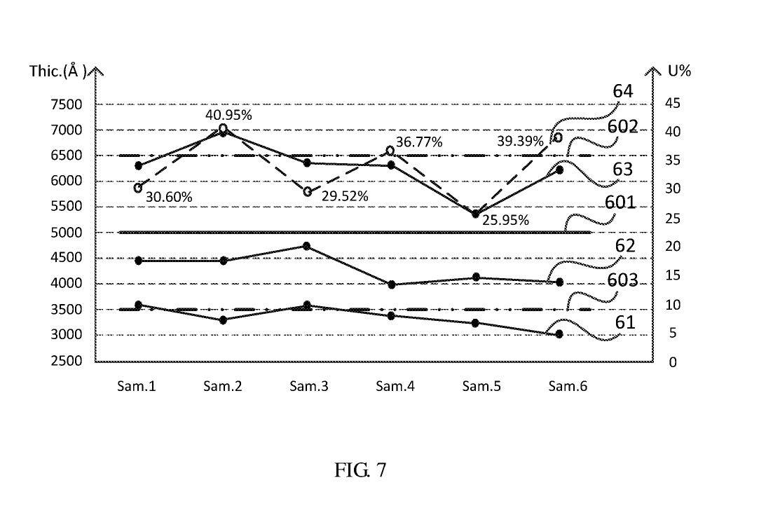

Optionally, FIG. 7 is a schematic diagram of the remaining thicknesses of the third regions of the photoresist layers of the six different samples provided in some embodiments of the present disclosure. Referring to FIGS. 3 and 7, the horizontal axis represents different sample numbers, Sam. 1 to Sam. 6 represent six samples of different sizes, the two vertical axes represent the retained thickness Thic. and the retained thickness uniformity U % of photoresist layer 24, respectively, the unit of retained thickness Thic. of photoresist layer 24 being Amy (Å). Line 601 represents the average value of the remaining target thickness of photoresist layer 24, optionally 0.5 microns, line 602 represents the maximum value of the remaining target thickness of photoresist layer 24, optionally 0.65 microns, line 603 represents the minimum value of the remaining target thickness of photoresist layer 24, optionally 0.35 microns; The dots on the fold line 61 represent the minimum value of the actual retained thickness of the photoresist layer 24, and the optional values range from 0.3 micron to 0.36 microns; the dots on the fold line 63 represent the maximum value of the actual retained thickness of the photoresist layer 24, and the optional values range from 0.54 microns to 0.69 microns; the dots on the fold line 62 represent the average value of the actual retained thickness of the photoresist layer 24, and the optional values range from 0.4 microns to 0.47 microns; The dots on the fold line 64 represent the uniformity of the actual remaining thickness of the photoresist layer 24, with optional values ranging from 25.95% to 40.95%.

Optionally, the manufacturing method includes two wet etches and two dry etches, and the wet etches and the dry etches are alternately performed. Specifically, it may include: first wet etching, patterning the source-drain electrode layer to form a metal wire structure of the source electrode region, the drain electrode region and the active region; First dry etching to form an island structure of semiconductor layer (including an active layer and a doped layer), i.e. an patterned semiconductor layer (including an active layer and a doped layer); a second wet etching, patterning the source-drain electrode layer to form a source electrode in the source electrode region and a drain electrode in the drain electrode region; In the second dry etching, the semiconductor layer (including the active layer and the doped layer) is etched, that is, the semiconductor layer (including the active layer and the doped layer) is etched to form an active switch structure.

Optionally, the dry etching may be over etched by 10%, and optionally, the etching time is 76 seconds, thereby further reducing the portions of the semiconductor layer beyond the source electrode and drain electrode.

Optionally, the feature size loss on each side of photoresist layer 414 is 0.94 microns.

Optionally, the manufacturing method further includes performing at least one photoresist ashing operation, the photoresist ashing operation being defined between the dry etching operation and the wet etching operation. Specifically, after the first dry etching, a photoresist ashing operation is performed before the second wet etching to remove the photoresist in the third region to expose the source-drain electrode layer in the channel region.

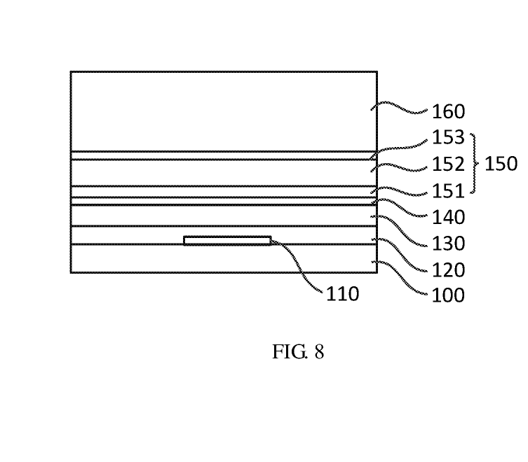

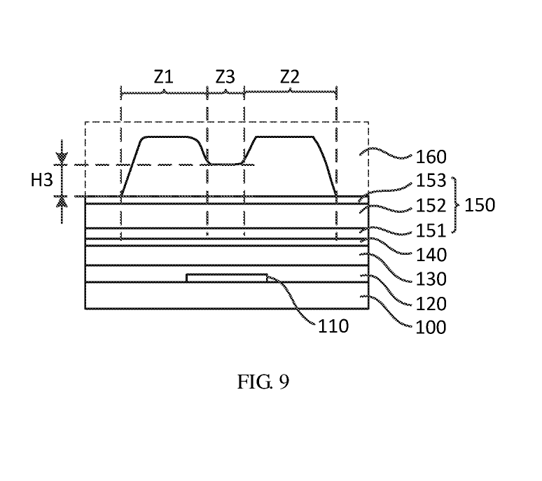

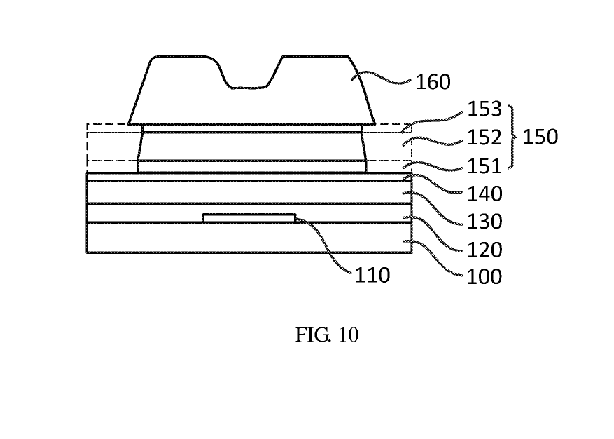

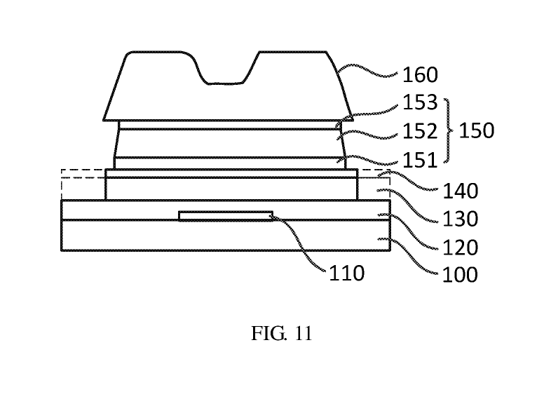

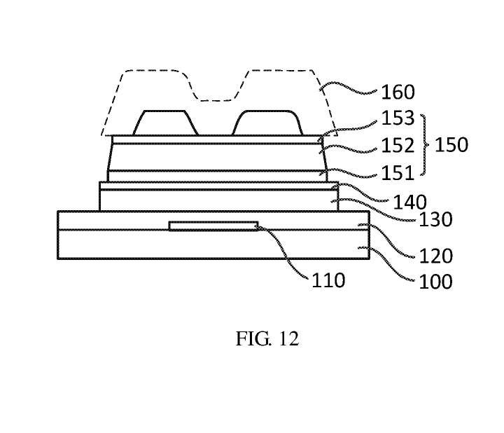

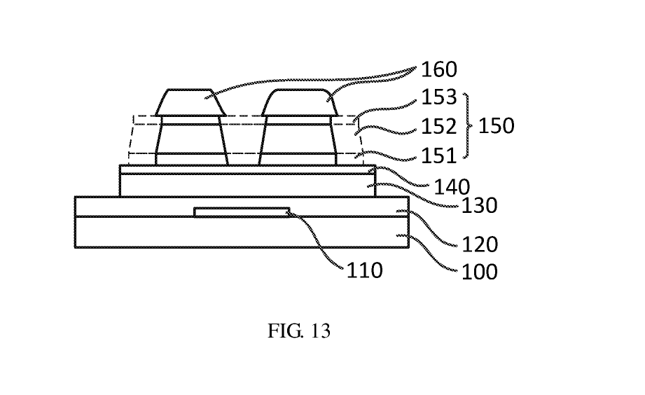

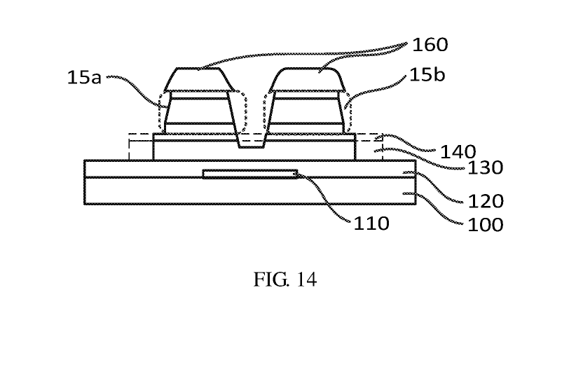

Optionally, FIGS. 8 to 14 are schematic diagrams of the film layer structures formed after each operation of the manufacturing method of the array substrate according to the embodiment of the present disclosure, which includes two wet etches, two dry etches, and one photoresist ashing. Taking the example of forming a bottom gate electrode type active switch of the array substrate, reference numerals are also used in FIGS. 8 to 14. Specifically, FIG. 8 is a schematic structural diagram of a film layer after depositing a photoresist layer in the manufacturing method of the array substrate provided in some embodiments of the present disclosure. Referring to FIG. 8, the specific structure may include a gate electrode 110, a gate electrode insulating layer 120, a semiconductor layer (including an active layer 130 and a doped layer 140), a source electrode-drain electrode layer 150 and a photoresist layer 160 which are sequentially provided on the substrate 100, and the source electrode-drain electrode layer 150 may include a molybdenum nitride layer 151, an aluminum layer 152 and a molybdenum nitride layer 153 which are sequentially stacked. The active layer 130 and the doped layer 140 together form a semiconductor layer (no reference number is further provided in FIG. 8). FIG. 9 is a schematic diagram of a film layer structure after patterning a photoresist layer in the manufacturing method of the array substrate provided in some embodiments of the present disclosure. Referring to FIG. 9, the photoresist layer 160 is patterned to form a patterned photoresist layer 160, the patterned photoresist layer 160 includes a first region Z1 and a second region Z2, and a third region Z3 located between the first region Z1 and the second region Z2, and the thickness H3 of the third region Z3 ranges from 0.2 microns to 0.8 microns. FIG. 10 is a schematic diagram of a film layer structure after the first wet etching in the manufacturing method of the array substrate provided in some embodiments of the present disclosure. Referring to FIG. 10, after the first wet etching, the source-drain electrodes layer 150 is patterned. FIG. 11 is a schematic structural diagram of a film layer after the first dry etching in the manufacturing method of the active switch provided in some embodiments of the present disclosure. Referring to FIG. 11, after the first dry etching, the semiconductor layer (including the active layer 130 and the doped layer 140) is patterned. FIG. 12 is a schematic diagram of a film layer structure after photoresist ashing in the manufacturing method of the array substrate provided in some embodiments of the present disclosure. Referring to FIG. 12, after photoresist ashing, the source-drain electrode layer 150 in the channel region is exposed. FIG. 13 is a schematic diagram of the structure of the film layer after the second wet etching in the manufacturing method of the array substrate provided in some embodiments of the present disclosure. referring to FIG. 13, after the second wet etching, the source electrode-drain electrode layer 150 is patterned, the source electrode 15a is formed in the source electrode region (the region corresponding to the first region Z1 of the photoresist layer 24), and the drain electrode 15b is formed in the drain electrode region (the region corresponding to the second region z2 of the photoresist layer 24). FIG. 14 is a schematic diagram of the structure of the film layer after the second dry etching in the manufacturing method of the array substrate provided in some embodiments of the present disclosure. Referring to FIG. 14, after the second dry etching, the semiconductor layer (including the active layer 130 and the doped layer 140) is etched to form the array substrate structure, especially the active switch structure on the array substrate. It should be noted that FIGS. 8 to 14 show the array substrate, especially, show the formation flow of the active switch of the array substrate, and an absent portion in the latter figure comparing with the previous image is the portion removed in the corresponding operation.

The active switch structure of the array substrate thus formed reduces the portions of the semiconductor layer beyond the source electrode and drain electrode, that is, the portions of the active layer beyond the source electrode and drain electrode are reduced, and the portions of the doped layer beyond the source electrode and the drain electrode are reduced, thereby reducing the light absorption by the semiconductor layer of the active switch of the array substrate and the probability of generating photo-generated carriers, as well as reducing the leakage current of the active switch, and correspondingly improving the stability of the active switch.

Optionally, the ratio of the lateral etching rate to the longitudinal etching rate in the photoresist ashing operation ranges from 1:0.9 to 1:1.5.

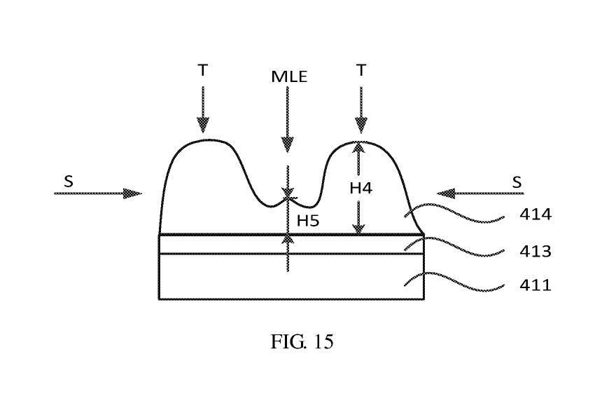

Optionally, FIG. 15 is a schematic diagram of the etching direction of the photoresist layer of the array substrate provided in some embodiments of the present disclosure. Referring to FIG. 15, a multi-layer functional layer 413 (which may include a gate electrode, a gate electrode insulating layer, a semiconductor layer and a source-drain electrodes layer, not specifically divided in FIG. 15 and all shown at 413) and a patterned photoresist layer 414 are formed on the substrate 411. In the photoresist ashing process, the ratio of the lateral (S direction in FIG. 15) etching rate to the longitudinal (T direction in FIG. 15) etching rate ranges from 1:0.9 to 1:1.5. Optionally, H4 is located in the first region or the second region of the photoresist layer and H5 is located in the third region of the photoresist layer. And, due to the micro-island effect in the ashing process of the photoresist layer 414, that is, the thickness of the middle portion of the third region of the photoresist layer 414 is thicker than the edge portion of the third region, as shown by MLE in FIG. 15, therefore, proper controlling of the etching rate in the ashing process may ensure complete removal of the third region of the photoresist layer 414.

Optionally, in the photoresist ashing operation, the etching gas includes sulfur hexafluoride and oxygen.

Optionally, when the ratio of the lateral etching rate to the longitudinal etching rate is 1:0.9, the etching gas is oxygen. When the ratio of lateral etching rate to longitudinal etching rate is 1:1.5, the etching gas is sulfur hexafluoride and oxygen, and the flow ratio of sulfur hexafluoride to oxygen ranges from 0.02 to 0.1.

In the photoresist ashing operation, gas generates plasma under the action of a radio frequency power source electrode in a vacuum environment, and the plasma bombards or reacts with the surface of the photoresist layer with high energy to ash the photoresist layer, i.e., the photoresist layer is thinned or removed. By adding sulfur hexafluoride gas, the longitudinal etching rate of the photoresist layer may be accelerated, and by controlling the type and flow rate of the gas, the ratio of the lateral etching rate to the longitudinal etching rate of the photoresist layer may be controlled to vary in the range of 1:0.9 to 1:1.5.

Optionally, the flow rate of sulfur hexafluoride ranges from 200 sccm to 800 sccm, and the flow rate of oxygen ranges from 8000 sccm to 10000 sccm, so that the ratio of the lateral etching rate to the longitudinal etching rate of the photoresist layer is controlled to range from 1:0.9 to 1:1.5.

Therefore, the first region of the photoresist layer after the photoresist ashing operation precisely covers the source electrode and the second region precisely covers the drain electrode, that is, the projection of the first region of the photoresist layer on the substrate is nearly coincident with the projection of the source electrode of the active switch on the substrate, and the projection of the second region of the photoresist layer on the substrate is nearly coincident with the projection of the drain electrode of the active switch on the substrate, so that in the subsequent dry etching process, the portions of the semiconductor layer (including the active layer and the doped layer) beyond the photoresist layer are etched away, that is, the portions of the semiconductor layer (including the active layer and the doped layer) beyond the source electrode and drain electrode are etched away, so that the active switch structure formed on the array substrate reduces the portions of the semiconductor layer beyond the source electrode and drain electrode, that is, the portions of the active layer beyond the source electrode and drain electrode, and the portions of the doped layer beyond the source electrode and drain electrode, thereby reducing the light absorption by the semiconductor layer of the active switch, and the possibility of generating photo-generated carriers, as well as reducing the leakage current of the active switch, and correspondingly improving the stability of the active switch

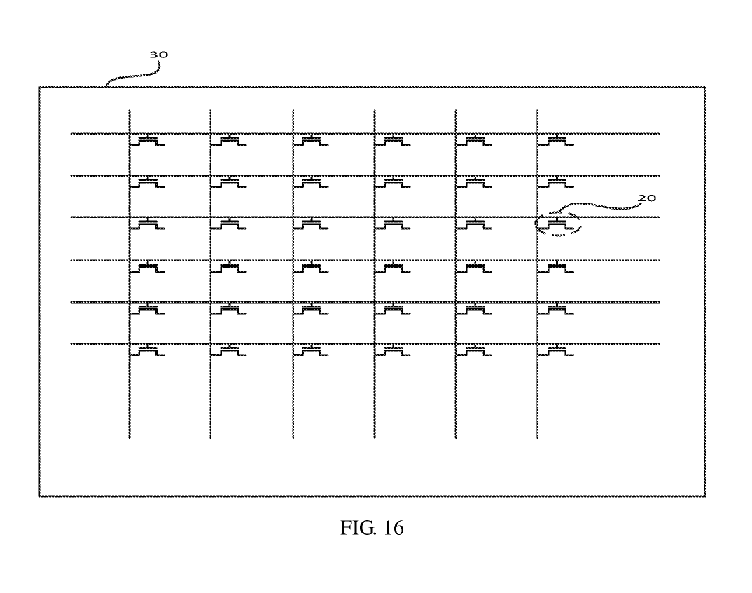

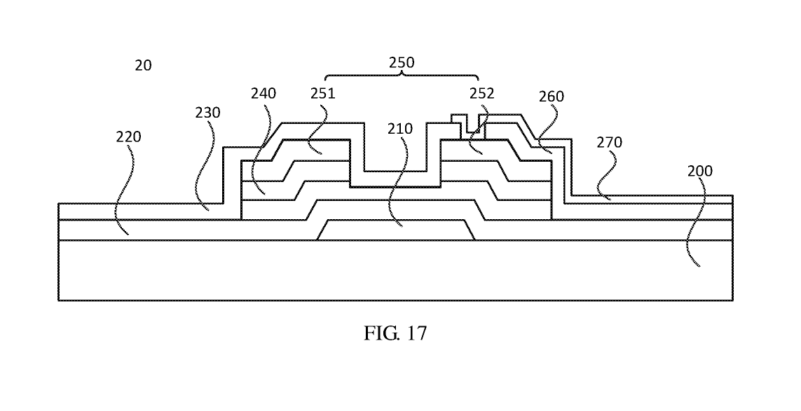

FIG. 16 is a schematic structural diagram of an array substrate provided in some embodiments of the present disclosure. Referring to FIG. 16, the array substrate 30 is defined with a plurality of active switches 20, and the active switches are formed by the manufacturing method provided in the above embodiment. FIG. 17 is a schematic structural diagram of an active switch of an array substrate according to some embodiments of the present disclosure. Referring to FIG. 17, the active switch 20 includes a substrate 200; a gate electrode 210, a gate electrode insulating layer 220, a semiconductor layer (including an active layer 230 and a doped layer 240), a source electrode 251 and a drain electrode 252 (source-drain electrodes 250) all formed on the substrate 200. The distance between the projection profile of the active layer 230 on the substrate 200 and the projection profile of the source electrode 251 or the drain electrode 252 on the substrate 200 ranges from 0 to 1.5 microns. The distance between the projection profile of the doping layer 240 on the substrate 200 and the projection profile of the source electrode 251 or the drain electrode 252 on the substrate 200 ranges from 0 to 1.0 microns.

And the smaller the distance between the projection profile of the active layer 230 on the substrate 200 and the projection profile of the source electrode 251 or the drain electrode 252 on the substrate 200, the smaller the probability that the active layer 230 absorbs light, thereby reducing the probability that the active switch may generate photo-generated carriers, that is, reducing the leakage current of the active switch. Similarly, the smaller the distance between the projection profile of the doping layer 240 on the substrate 200 and the projection profile of the source electrode 251 or the drain electrode 252 on the substrate 200, the smaller the probability of absorbing light absorption by the doping layer 240, thus reducing the probability of generating photo-generated carriers by the active switch, that is, reducing the leakage current of the active switch.

Optionally, the distance between the projection profile of the active layer 230 on the substrate 200 and the projection profile of the source electrode 251 or the drain electrode 252 on the substrate 200 may be 0 to 0.8 microns, and the distance between the projection profile of the doped layer 240 on the substrate 200 and the projection profile of the source electrode 251 or the drain electrode 252 on the substrate 200 may be 0 to 0.5 microns. Optionally, when the projection profile of the active layer 230 on the substrate 200 is 0 micron apart from the projection profile of the source electrode 251 or the drain electrode 252 on the substrate 200, and the projection profile of the doping layer 240 on the substrate 200 is 0 micron apart from the projection profile of the source electrode 251 or the drain electrode 252 on the substrate 200, the semiconductor layer (including the active layer 230 and the doping layer 240) does not absorb light and no photo-generated carriers are generated in the active switch, so that the leakage current of the active switch is 0 and the stability of the corresponding active switch is high.

It should be noted that the active switches of 6 rows and 6 columns are optionally shown in FIG. 16, but are not limited to the array substrate in the present disclosure, and the amount and arrangement of the active switches may be designed according to the actual requirements of the array substrate. FIG. 17 optionally shows that the distance between the projection profile of the active layer 230 on the substrate 200 and the projection profile of the source electrode 251 or the drain electrode 252 on the substrate 200 is equal to 0. The distance between the projection profile of the doping layer 240 on the substrate 200 and the projection profile of the source electrode 251 or the drain electrode 252 on the substrate 200 is equal to 0.

The array substrate provided in some embodiments of the present disclosure includes the above-mentioned active switch, which reduces the portions of the semiconductor layer beyond the source electrode and drain electrode, i.e., the portions of the active layer beyond the source electrode and drain electrode, and the portions of the doped layer beyond the source electrode and drain electrode, thereby reducing the light absorption by the semiconductor layer of the active switch of the array substrate and the possibility of generating photo-generated carriers, as well as reducing the leakage current of the active switch and correspondingly improving the stability of the active switch.

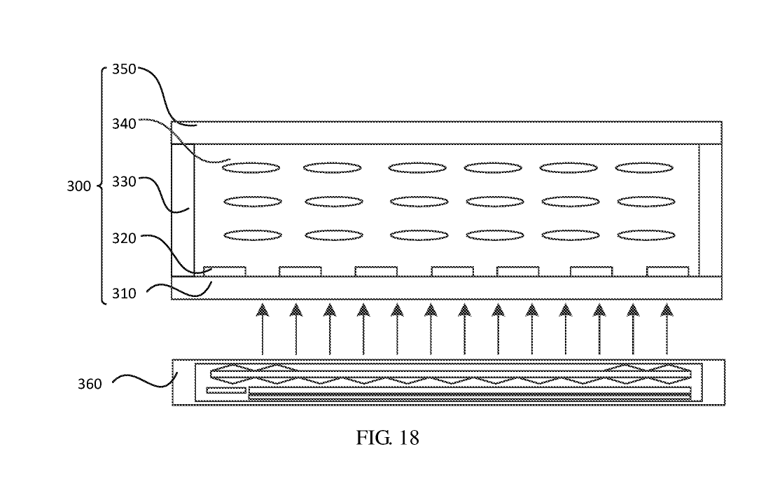

Embodiments of the present disclosure also provide a liquid crystal display device. FIG. 18 is a structural schematic diagram of a liquid crystal display device provided in some embodiments of the present disclosure. Referring to FIG. 18, the display device includes a display panel 300 and a backlight module 360, the display panel 300 includes the array substrate 310 provided above, the backlight module 360 is defined on one side of the display panel 300, and the backlight module 360 is optionally defined under the display panel 300 shown in FIG. 18.

Optionally, the display panel 300 includes an array substrate 310, a pixel electrode 320, a encapsulation layer 330, a liquid crystal molecule layer 340 and a common electrode 350, and the deflection of the liquid crystal molecules in the liquid crystal molecule layer 340 is controlled by applying an electric field between the pixel electrode 320 and the common electrode 350, thereby realizing display. It should be noted that as shown in FIG. 17, the active switch is electrically connected to the pixel electrode 270 (pixel electrode 320 in FIG. 18) though a via hole in the insulating layer 260, thereby transmitting a data line signal to the corresponding pixel electrode 270 (pixel electrode 320 in FIG. 18) when the active switch is turned on, and other structures of the liquid crystal display device will not be specifically shown here. Compared with the technology in prior art, the structure of the active switch of the array substrate reduces the portions of the semiconductor layer beyond the source electrode and drain electrode, that is, the portions of the active layer beyond the source electrode and drain electrode, and the portions of the doped layer beyond the source electrode and drain electrode, thereby reducing the probability of light absorption by the semiconductor layer of the active switch of the array substrate and the probability of generating photo-generated carriers, as well as reducing the leakage current of the active switch and correspondingly improving the electrical performance stability of the active switch, and simultaneously reducing the power consumption of the display panel.

Those skilled in the art may understand that the application range of the active switch of the array substrate includes but is not limited to display panels, and any electronic devices that may integrate the above active switch fall within the scope of protection of the present disclosure.

It is to be noted that the above are only optional embodiments of the present disclosure and the technical principles used by them. It may be understood by those skilled in the art that the present disclosure is not limited to the specific embodiments described herein, and various obvious changes, readjustments, combinations and substitutions may be made to those skilled in the art without departing from the scope of protection of the present disclosure. Therefore, although the present disclosure has been described in more detail through the above embodiments, the present disclosure is not limited to the above embodiments, but may include more equivalent embodiments without departing from the concept of the present disclosure, and the scope of the present disclosure is determined by the scope of the appended claims.

What is claimed is:

1. A manufacturing method of an array substrate, wherein the array substrate comprises a plurality of active switches, the manufacturing method comprises:
providing a substrate;
forming a gate electrode, a gate insulating layer, a semiconductor layer, a source-drain electrode layer, and a photoresist layer all on the substrate;
patterning the photoresist layer to form a patterned photoresist layer, wherein the patterned photoresist layer comprises a first region, a second region, and a third region between the first region and the second region, and the thickness of the third region ranges from 0.2 microns to 0.8 microns; and,
patterning the source-drain electrode layer by using the patterned photoresist layer as a mask, forming a source electrode of the active switch in a portion covered by the first region, forming the drain electrode of the active switch in a portion covered by the second region, patterning the semiconductor layer, and forming a channel region of the active switch in the portion covered by the third region.

2. The manufacturing method according to claim 1, wherein the photoresist layer is patterned by using a halftone mask process, and the value of illumination energy required to expose the third region is in the range of 37 millijoules to 48 millijoules.

3. The manufacturing method according to claim 2, wherein the patterning the source-drain electrode layer comprises at least one wet etching of the source-drain electrode layer; patterning the semiconductor layer comprises at least one dry etching of the semiconductor layer.

4. The manufacturing method according to claim 1, wherein: patterning the source-drain electrode layer comprises at least one wet etching of the source-drain electrode layer; patterning the semiconductor layer comprises at least one dry etching of the semiconductor layer.

5. The manufacturing method according to claim 4, wherein the manufacturing method comprises two wet etches and two dry etches, and the wet etches and the dry etches are alternately performed.

6. The manufacturing method according to claim 4, wherein the manufacturing method further comprises performing at least one photoresist ashing operation which is defined between the wet etching and the dry etching operations.

7. The manufacturing method according to claim 6, wherein the ratio of the lateral etching rate to the longitudinal etching rate in the photoresist ashing operation ranges from 1:0.9 to 1:1.5.

8. The manufacturing method according to claim 7, wherein in the photoresist ashing operation, the etching gas comprises sulfur hexafluoride and oxygen.

9. The manufacturing method according to claim 8, wherein the flow rate of sulfur hexafluoride ranges from 200 standard cubic centimeter per minute to 800 standard cubic centimeter per minute; the flow rate of oxygen ranges from 8000 standard cubic centimeter per minute to 10000 standard cubic centimeter per minute.

10. An array substrate, defined with a plurality of active switches, the array substrate comprising:
a substrate;
a semiconductor layer, a source electrode, and a drain electrode all formed on the substrate;
wherein the source electrode and the drain electrode are located on one side of the semiconductor layer away from the substrate;
the distance between the projection profile of the semiconductor layer on the substrate and the projection profile of the source electrode or the drain electrode on the substrate ranges from 0 to 1.5 microns; the distance between the projection profile of the doping layer on the substrate and the projection profile of the source electrode or the drain electrode on the substrate ranges from 0 to 1.0 microns.

11. The array substrate of claim 10, wherein a manufacturing method of the array substrate comprises:
providing a substrate;
forming a gate electrode, a gate insulating layer, a semiconductor layer, a source-drain electrode layer and a photoresist layer all on the substrate;
patterning the photoresist layer to form a patterned photoresist layer, wherein the patterned photoresist layer comprises a first region, a second region, and a third region between the first region and the second region, and the thickness of the third region ranges from 0.2 microns to 0.8 microns; and,
patterning the source-drain electrode layer by using the patterned photoresist layer as a mask, forming a source electrode of the active switch in a portion covered by the first region, forming the drain electrode of the active switch in a portion covered by the second region, patterning the semiconductor layer, and forming a channel region of the active switch in the portion covered by the third region.

12. The array substrate according to claim 11, wherein the photoresist layer is patterned by using a halftone mask process, and the value of illumination energy required to expose the third region is in the range of 37 millijoules to 48 millijoules.

13. The array substrate of claim 11, wherein the patterning the source-drain electrode layer comprises at least one wet etching of the source-drain electrode layer; the patterning of the semiconductor layer comprises at least one dry etching of the semiconductor layer.

14. The array substrate according to claim 13, wherein the manufacturing method comprises two wet etches and two dry etches, and the wet etches and the dry etches are alternately performed.

15. The array substrate of claim 14, wherein the manufacturing method further comprises performing at least one photoresist ashing operation which is defined between the wet etching and the dry etching operations.

16. The array substrate according to claim 15, wherein the ratio of the lateral etching rate to the longitudinal etching rate in the photoresist ashing operation ranges from 1:0.9 to 1:1.5.

17. A manufacturing method of an array substrate, wherein the array substrate comprises a plurality of active switches, the manufacturing method comprises:
providing a substrate;
forming a gate electrode, a gate insulating layer, a semiconductor layer, a source-drain electrode layer and a photoresist layer all on the substrate;
patterning the photoresist layer to form a patterned photoresist layer, wherein the patterned photoresist layer comprises a first region, a second region, and a third region between the first region and the second region, and the thickness of the third region ranges from 0.2 microns to 0.8 microns; and,
patterning the source-drain electrode layer by using the patterned photoresist layer as a mask, forming a source electrode of the active switch in a portion covered by the first region, forming the drain electrode of the active switch in a portion covered by the second region, patterning the semiconductor layer, and forming a channel region of the active switch in the portion covered by the third region;
wherein the manufacturing method further comprises performing at least one photoresist ashing operation;
in the photoresist ashing operation, the ratio of the lateral etching rate to the longitudinal etching rate in the photoresist ashing operation ranges from 1:0.9 to 1:1.5;
and when the ratio of the lateral etching rate to the longitudinal etching rate is 1:1.5, the ratio of the flow rate of sulfur hexafluoride to the flow rate of oxygen ranges in 0.02 to 0.1.
